(19) United States
(12) Patent Application Publication
(10) Pub. No.: US 2025/0038126 A1
(43) Pub. Date: Jan. 30, 2025

(54) SEMICONDUCTOR PACKAGE HAVING ELECTROMAGNETIC INTERFERENCE SHIELDING STRUCTURE

(71) Applicant: MEDIATEK INC., Hsin-Chu (TW)

(72) Inventors: De-Wei Liu, Hsinchu City (TW); Pu-Shan Huang, Hsinchu City (TW); Sang-Mao Chiu, Hsinchu City (TW); Shih-Yi Syu, Hsinchu City (TW)

(73) Assignee: MEDIATEK INC., Hsin-Chu (TW)

(21) Appl. No.: 18/784,941

(22) Filed: Jul. 26, 2024

Related U.S. Application Data
(60) Provisional application No. 63/516,181, filed on Jul. 28, 2023.

(51) Int. Cl. H01L 23/552; H01L 23/00; H01L 23/055; H01L 23/31; H01L 23/36; H01L 23/498; H01L 23/58

(52) U.S. Cl. CPC H01L 23/552; H01L 23/055; H01L 23/49822; H01L 23/585; H01L 23/3107; H01L 23/36; H01L 23/49816; H01L 24/16; H01L 24/32; H01L 24/33; H01L 24/73; H01L 2224/16225; H01L 2224/32225; H01L 2224/32245; H01L 2224/33181; H01L 2224/33519; H01L 2224/73204; H01L 2224/73253

(57) ABSTRACT

A semiconductor package includes a substrate having a top surface and a bottom surface, and a vertical sidewall extending between the top surface and the bottom surface; an integrated circuit die mounted within a device region on the top surface of the substrate; a metal interconnect structure embedded within the device region of the substrate, wherein the integrated circuit die is electrically connected to the metal interconnect structure; and a peripheral shielding ring embedded within a peripheral region of the substrate. The peripheral region surrounds the device region. A lid is mounted on the top surface of the substrate. The lid is electrically connected with the peripheral shielding ring.

### CROSS REFERENCE TO RELATED APPLICATIONS

This application claims the benefit of U.S. Provisional Application No. 63/516,181, filed on Jul. 28, 2023. The content of the application is incorporated herein by reference.

### BACKGROUND

The present invention relates to a semiconductor package, and in particular, to a semiconductor package having an electromagnetic interference (EMI) shielding structure.

In order to ensure the continued miniaturization and multi-functionality of electronic products and communication devices, it is desired that semiconductor packages be small in size, support multi-pin connection, operate at high speeds, and have high functionality.

In such semiconductor packages, the integrated circuit chips incorporated therein may be subject to disturbance by electromagnetic interference (EMI). EMI may cause the semiconductor packages to exhibit abnormal operation and poor performance. To shield the semiconductor package from EMI, a metal shielding layer is disposed on an encapsulant of the semiconductor package.

### SUMMARY

It is one object of the invention to provide an improved semiconductor package having an electromagnetic interference (EMI) shielding structure.

One aspect of the invention provides a semiconductor package including a substrate having a top surface and a bottom surface, and a vertical sidewall extending between the top surface and the bottom surface; an integrated circuit die mounted within a device region on the top surface of the substrate; a metal interconnect structure embedded within the device region of the substrate, wherein the integrated circuit die is electrically connected to the metal interconnect structure; and a peripheral shielding ring embedded within a peripheral region of the substrate. The peripheral region surrounds the device region. A lid is mounted on the top surface of the substrate. The lid is electrically connected with the peripheral shielding ring.

According to some embodiments, the lid is a metal lid.

According to some embodiments, the lid is directly mounted on the peripheral shielding ring by using a solder paste.

According to some embodiments, the peripheral shielding ring is spaced apart from the metal interconnect structure.

According to some embodiments, the peripheral shielding ring penetrates through an entire thickness of the substrate.

According to some embodiments, the peripheral shielding ring comprises an annular bottom pad disposed within the peripheral region of the substrate and exposed from the bottom surface of the substrate.

According to some embodiments, the semiconductor package further includes a plurality of ball grid array (BGA) balls disposed within the device region on the bottom surface of the substrate; and a plurality of peripheral solder balls mounted on the annular bottom pad.

According to some embodiments, the peripheral shielding ring comprises a plurality of metal layers and a plurality of metal vias.

According to some embodiments, the semiconductor package further includes an encapsulant enclosing the integrated circuit die and the top surface of the substrate.

According to some embodiments, the integrated circuit die is in thermal contact with the lid, and wherein a thermal interface material (TIM) layer is disposed between the integrated circuit die and the lid.

Another aspect of the invention provides a semiconductor package including a substrate having a top surface and a bottom surface, and a vertical sidewall extending between the top surface and the bottom surface; an integrated circuit die mounted within a device region on the top surface of the substrate; and a metal interconnect structure embedded within the device region of the substrate, wherein the integrated circuit die is electrically connected to the metal interconnect structure; and a peripheral shielding ring embedded within a peripheral region of the substrate. The peripheral region surrounds the device region. The metal interconnect structure comprises a ground plane. The peripheral shielding ring is electrically connected to the ground plane. A lid is mounted on the top surface of the substrate, wherein the lid is electrically connected with the peripheral shielding ring.

According to some embodiments, the lid is a metal lid.

According to some embodiments, the lid is directly mounted on the peripheral shielding ring by using a solder paste.

According to some embodiments, the peripheral shielding ring is spaced apart from the metal interconnect structure.

According to some embodiments, the peripheral shielding ring penetrates through an entire thickness of the substrate.

According to some embodiments, the peripheral shielding ring comprises an annular bottom pad disposed within the peripheral region of the substrate and exposed from the bottom surface of the substrate.

According to some embodiments, the semiconductor package further includes a plurality of ball grid array (BGA) balls disposed within the device region on the bottom surface of the substrate; and a plurality of peripheral solder balls mounted on the annular bottom pad.

According to some embodiments, the peripheral shielding ring comprises a plurality of metal layers and a plurality of metal vias.

According to some embodiments, the semiconductor package further includes an encapsulant enclosing the integrated circuit die and the top surface of the substrate.

According to some embodiments, the integrated circuit die is in thermal contact with the lid, and wherein a thermal interface material (TIM) layer is disposed between the integrated circuit die and the lid.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a partial perspective view of an exemplary semiconductor package according to an embodiment of the present invention;

FIG. 2 is a schematic, cross-sectional view taken along line I-I′ in FIG. 1; and

FIG. 3 is a schematic, cross-sectional diagram showing an exemplary semiconductor package according to another embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, structural, and procedural changes may be made without departing from the spirit and scope of the present disclosure. The following detailed description is, therefore, not to be taken in a limiting sense, and the scope of embodiments of the present invention is defined only by the appended claims.

It will be understood that, although the terms first, second, third, primary, secondary, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first or primary element, component, region, layer or section discussed below could be termed a second or secondary element, component, region, layer or section without departing from the teachings of the present inventive concept.

Spatially relative terms, such as “beneath”, “below”, “lower”, “under”, “above,” “upper,” “over” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” or “over” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

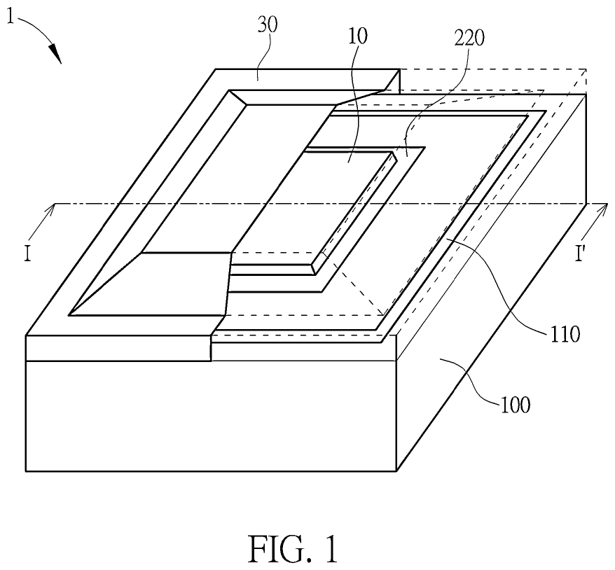

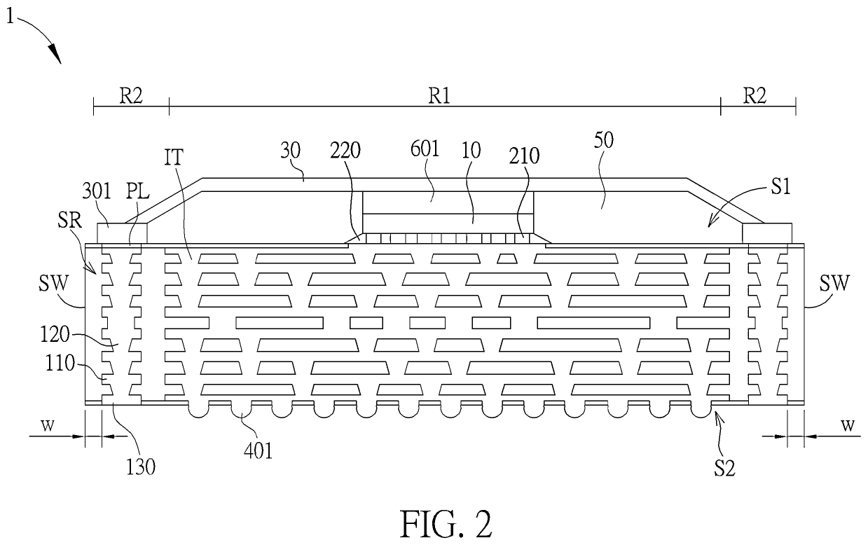

Please refer to FIG. 1 and FIG. 2. FIG. 1 is a partial perspective view of an exemplary semiconductor package according to an embodiment of the present invention. FIG. 2 is a schematic, cross-sectional view taken along line I-I′ in FIG. 1. As shown in FIG. 1 and FIG. 2, the semiconductor package 1 includes a substrate 100 having a top surface S1 and a bottom surface S2, and a vertical sidewall SW extending between the top surface S1 and the bottom surface S2. According to an embodiment of the invention, the substrate 100 may be a packaging substrate. According to an embodiment of the invention, for example, the substrate 100 may be a cored substrate having 3-2-3 construction including, but not limited to, three build-up layers on both sides of a two layer glass or epoxy core. For embodiments where the substrate 100 is a multi-layer board, signal lines, power lines, and ground planes can be distributed across different layers. This allows for more flexible routing, avoiding signal crosstalk and interference. Such configuration is beneficial for designs with high electrical demands, such as high-frequency signals, high-speed signals, and analog signals.

According to an embodiment of the invention, the substrate 100 comprises a device region R1 and an annular peripheral region R2 surrounding the device region R1. According to an embodiment of the invention, the substrate 100 comprises a metal interconnect structure IT embedded within the device region R1. According to an embodiment of the invention, for example, the metal interconnect structure IT may comprise a two-layered core and three build-up layers on both sides of the core.

According to an embodiment of the invention, the substrate 100 comprises a peripheral shielding ring SR embedded within the peripheral region R2 of the substrate 100. According to some embodiments, the peripheral shielding ring SR comprises a plurality of metal layers 110 and a plurality of metal vias 120. Each of the metal layers 110 may be a continuous, ring-shaped metal layer, as can be best seen in FIG. 1. These metal layers 110 are interconnected by the metal vias 120, thereby forming an EMI shielding wall around the device region R1 of the substrate 100. According to an embodiment of the invention, the distances between the outer edges of the metal layers and the vertical sidewall SW may be the same. According to an embodiment of the invention, the distance w between the outer edge of the peripheral shielding ring SR and the vertical sidewall SW may be equal to or greater than 300 micrometers. For embodiments where FCBGAs (Flip Chip Ball Grid Array) are utilized, the increased distance between the FCBGAs and the cutting streets can lead to uneven current distribution and excessive copper variation if different metal layers have various distances to the vertical sidewall SW. By providing such configuration where the distances between the outer edges of the metal layers and the vertical sidewall SW are substantially the same, the copper plating on the edges of the substrate can be more uniform during substrate production and the yield of substrate production can be increased.

According to some embodiments, the peripheral shielding ring SR within the peripheral region R2 is spaced apart from the metal interconnect structure IT within the device region R1. According to some embodiments, the peripheral shielding ring SR penetrates through an entire thickness of the substrate 100. According to some embodiments, the peripheral shielding ring SR comprises an annular bottom pad 130 that is disposed within the peripheral region R2 of the substrate 100 and is exposed from the bottom surface S2 of the substrate 100. According to an embodiment of the invention, the ground signal of the device region R1 can be connected to the ground signal of the peripheral shielding ring SR.

According to an embodiment of the invention, an integrated circuit die 10 is mounted within the device region R1 on the top surface S1 of the substrate 100. According to an embodiment of the invention, the integrated circuit die 10 is electrically connected to the metal interconnect structure IT through a plurality of connecting elements 210. According to an embodiment of the invention, for example, the plurality of connecting elements 210 may comprise conductive bumps, pillars, or micro-bumps, but not limited thereto. According to an embodiment of the invention, for example, a gap between the integrated circuit die 10 and the top surface S1 of the substrate 100 may be sealed by using an underfill 220.

According to an embodiment of the invention, a lid 30 is mounted on the top surface S1 of the substrate 100. The lid 30 covers and encloses the integrated circuit die 10. According to an embodiment of the invention, the lid 30 is electrically connected with the peripheral shielding ring SR. According to an embodiment of the invention, the lid 30 is a metal lid and may comprise, for example, aluminum or any suitable materials. According to an embodiment of the invention, a base portion 301 of the lid 30 is directly mounted on the peripheral shielding ring SR by using a solder paste PL.

According to an embodiment of the invention, the semiconductor package 1 may further include a plurality of ball grid array (BGA) balls 401 disposed within the device region R1 on the bottom surface S2 of the substrate 100.

According to an embodiment of the invention, optionally, the semiconductor package 1 may further include an encapsulant 50 enclosing the integrated circuit die 10 and the top surface S1 of the substrate 100. In some embodiments, the encapsulant 50 may be omitted. According to an embodiment of the invention, the integrated circuit die 10 is in thermal contact with the lid 30. According to an embodiment of the invention, optionally, a thermal interface material (TIM) layer 601 may be disposed between the integrated circuit die 10 and the lid 30. In some embodiments, the TIM layer 601 may include a thermal gel, a graphite sheet, a metal sheet, or the like, or combinations thereof.

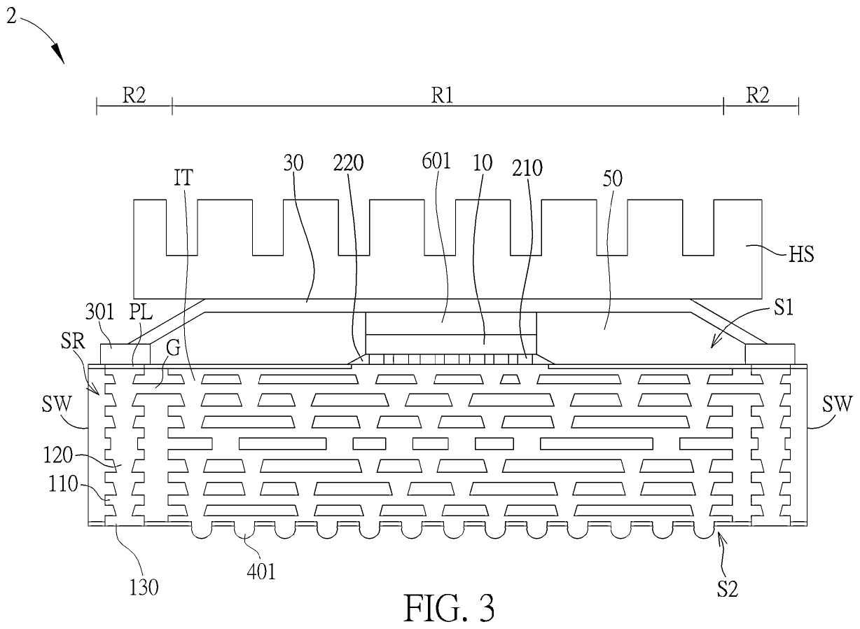

FIG. 3 is a schematic, cross-sectional diagram showing an exemplary semiconductor package according to another embodiment of the invention, wherein like numeral numbers designate like regions, layers or elements. As shown in FIG. 3, likewise, the semiconductor package 2 includes a substrate 100 having a top surface S1 and a bottom surface S2, and a vertical sidewall SW extending between the top surface S1 and the bottom surface S2. According to an embodiment of the invention, the substrate 100 may be a packaging substrate. According to an embodiment of the invention, for example, the substrate 100 may be a cored substrate having 3-2-3 construction including, but not limited to, three build-up layers on both sides of a two layer glass or epoxy core.

According to an embodiment of the invention, the substrate 100 comprises a device region R1 and an annular peripheral region R2 surrounding the device region R1. According to an embodiment of the invention, the substrate 100 comprises a metal interconnect structure IT embedded within the device region R1. According to an embodiment of the invention, for example, the metal interconnect structure IT may comprise a two-layered core and three build-up layers on both sides of the core. According to an embodiment of the invention, the metal interconnect structure IT comprises a ground plane G.

According to an embodiment of the invention, the substrate 100 comprises a peripheral shielding ring SR embedded within the peripheral region R2 of the substrate 100. According to some embodiments, the peripheral shielding ring SR comprises a plurality of metal layers 110 and a plurality of metal vias 120. Each of the metal layers 110 may be a continuous, ring-shaped metal layer. These metal layers 110 are interconnected by the metal vias 120, thereby forming an EMI shielding wall around the device region R1 of the substrate 100. According to an embodiment of the invention, the peripheral shielding ring SR is electrically connected to the ground plane G. The heat dissipation can be improved and a more complete and larger area of interference shielding capability can be achieved.

According to an embodiment of the invention, the distances between the outer edges of the metal layers and the vertical sidewall SW may be the same. According to an embodiment of the invention, the distance w between the outer edge of the peripheral shielding ring SR and the vertical sidewall SW may be equal to or greater than 300 micrometers.

According to some embodiments, the peripheral shielding ring SR within the peripheral region R2 is spaced apart from the metal interconnect structure IT within the device region R1. According to some embodiments, the peripheral shielding ring SR penetrates through an entire thickness of the substrate 100. According to some embodiments, the peripheral shielding ring SR comprises an annular bottom pad 130 that is disposed within the peripheral region R2 of the substrate 100 and is exposed from the bottom surface S2 of the substrate 100.

According to an embodiment of the invention, an integrated circuit die 10 is mounted within the device region R1 on the top surface S1 of the substrate 100. According to an embodiment of the invention, the integrated circuit die 10 is electrically connected to the metal interconnect structure IT through a plurality of connecting elements 210. According to an embodiment of the invention, for example, the plurality of connecting elements 210 may comprise conductive bumps, pillars, or micro-bumps, but not limited thereto. According to an embodiment of the invention, for example, a gap between the integrated circuit die 10 and the top surface S1 of the substrate 100 may be sealed by using an underfill 220.

According to an embodiment of the invention, a lid 30 is mounted on the top surface S1 of the substrate 100. The lid 30 covers and encloses the integrated circuit die 10. According to an embodiment of the invention, the lid 30 is electrically connected with the peripheral shielding ring SR. According to an embodiment of the invention, the lid 30 is a metal lid and may comprise, for example, aluminum or any suitable materials. According to an embodiment of the invention, a base portion 301 of the lid 30 is directly mounted on the peripheral shielding ring SR by using a solder paste PL.

According to an embodiment of the invention, the semiconductor package 1 may further include a plurality of ball grid array (BGA) balls 401 disposed within the device region R1 on the bottom surface S2 of the substrate 100. According to an embodiment of the invention, the semiconductor package 1 does not include a peripheral solder ball on the annular bottom pad 130.

According to an embodiment of the invention, optionally, the semiconductor package 1 may further include an encapsulant 50 enclosing the integrated circuit die 10 and the top surface S1 of the substrate 100. In some embodiments, the encapsulant 50 may be omitted. According to an embodiment of the invention, the integrated circuit die 10 is in thermal contact with the lid 30. According to an embodiment of the invention, optionally, a thermal interface material (TIM) layer 601 may be disposed between the integrated circuit die 10 and the lid 30. According to an embodiment of the invention, optionally, a heat sink HS may be disposed directly on the lid 30.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package, comprising:
a substrate having a top surface and a bottom surface, and a vertical sidewall extending between the top surface and the bottom surface;
an integrated circuit die mounted within a device region on the top surface of the substrate;
a metal interconnect structure embedded within the device region of the substrate, wherein the integrated circuit die is electrically connected to the metal interconnect structure;
a peripheral shielding ring embedded within a peripheral region of the substrate, wherein the peripheral region surrounds the device region; and
a lid mounted on the top surface of the substrate, wherein the lid is electrically connected with the peripheral shielding ring.

2. The semiconductor package according to claim 1, wherein the lid is a metal lid.

3. The semiconductor package according to claim 1, wherein the lid is directly mounted on the peripheral shielding ring by using a solder paste.

4. The semiconductor package according to claim 1, wherein the peripheral shielding ring is spaced apart from the metal interconnect structure.

5. The semiconductor package according to claim 1, wherein the peripheral shielding ring penetrates through an entire thickness of the substrate.

6. The semiconductor package according to claim 1, wherein the peripheral shielding ring comprises an annular bottom pad disposed within the peripheral region of the substrate and exposed from the bottom surface of the substrate.

7. The semiconductor package according to claim 6 further comprising:
a plurality of ball grid array (BGA) balls disposed within the device region on the bottom surface of the substrate; and
a plurality of peripheral solder balls mounted on the annular bottom pad.

8. The semiconductor package according to claim 1, wherein the peripheral shielding ring comprises a plurality of metal layers and a plurality of metal vias.

9. The semiconductor package according to claim 1 further comprising:
an encapsulant enclosing the integrated circuit die and the top surface of the substrate.

10. The semiconductor package according to claim 1, wherein the integrated circuit die is in thermal contact with the lid, and wherein a thermal interface material (TIM) layer is disposed between the integrated circuit die and the lid.

11. A semiconductor package, comprising:
a substrate having a top surface and a bottom surface, and a vertical sidewall extending between the top surface and the bottom surface;
an integrated circuit die mounted within a device region on the top surface of the substrate;
a metal interconnect structure embedded within the device region of the substrate, wherein the integrated circuit die is electrically connected to the metal interconnect structure, wherein the metal interconnect structure comprises a ground plane;
a peripheral shielding ring embedded within a peripheral region of the substrate, wherein the peripheral region surrounds the device region, wherein the peripheral shielding ring is electrically connected to the ground plane; and
a lid mounted on the top surface of the substrate, wherein the lid is electrically connected with the peripheral shielding ring.

12. The semiconductor package according to claim 11, wherein the lid is a metal lid.

13. The semiconductor package according to claim 11, wherein the lid is directly mounted on the peripheral shielding ring by using a solder paste.

14. The semiconductor package according to claim 11, wherein the peripheral shielding ring is spaced apart from the metal interconnect structure.

15. The semiconductor package according to claim 11, wherein the peripheral shielding ring penetrates through an entire thickness of the substrate.

16. The semiconductor package according to claim 11, wherein the peripheral shielding ring comprises an annular bottom pad disposed within the peripheral region of the substrate and exposed from the bottom surface of the substrate.

17. The semiconductor package according to claim 16 further comprising:
a plurality of ball grid array (BGA) balls disposed within the device region on the bottom surface of the substrate; and
a plurality of peripheral solder balls mounted on the annular bottom pad.

18. The semiconductor package according to claim 11, wherein the peripheral shielding ring comprises a plurality of metal layers and a plurality of metal vias.

19. The semiconductor package according to claim 11 further comprising:
an encapsulant enclosing the integrated circuit die and the top surface of the substrate.

20. The semiconductor package according to claim 11, wherein the integrated circuit die is in thermal contact with the lid, and wherein a thermal interface material (TIM) layer is disposed between the integrated circuit die and the lid.
